(19) United States
(12) Patent Application Publication
(10) Pub. No.: US 2007/0042602 A1
(43) Pub. Date: Feb. 22, 2007

(54) Etch method using supercritical fluids

(75) Inventors: James J. Watkins, South Hadley, MA (US); Patrick A.Van Cleemput, Sunnyvale, CA (US); Ronald Powell, Portola Valley, CA (US)

Correspondence Address: FISH & RICHARDSON PC, P.O. BOX 1022, MINNEAPOLIS, MN, 55440-1022, US

(73) Assignees: The University of Massachusetts, a Massachusetts corporations,; and Novellus Systems, Inc. a California Corporation

(21) Appl. No.: 11/337,779

(22) Filed: Jan. 23, 2006

Related U.S. Application Data
(63) Continuation of application No. 10/637,947, filed on Aug. 7, 2003, now abandoned.
(60) Provisional application No. 60/402,250, filed on Aug. 9, 2002.

(51) Int. Cl. B44C 1/22; H01L 21/302

(52) U.S. Cl. 438/689; 216/83

(57) ABSTRACT

Methods are described for removing a material from a substrate by dissolving an etchant into a solvent to form a solution; and exposing the substrate to the solution so that the etchant in the solution removes material from the substrate; wherein during the exposure the solution is maintained in a supercritical or near-supercritical phase. The described methods can include additional steps, such as exposing a precursor of the material to a reagent to form the material, and depositing a second material onto the substrate after removing the material from the substrate.

### CROSS-REFERENCE TO RELATED APPLICATIONS

This application claims priority from U.S. Provisional Patent Application No. 60/402,250, entitled “ETCH METHOD USING SUPERCRITICAL FLUIDS,” and filed on Aug. 9, 2002, the entire contents of which are hereby incorporated by reference.

### TECHNICAL FIELD

This invention relates to methods for etching a material.

### BACKGROUND

Semiconductor industry growth continues to be driven by demand for smaller, faster, cheaper and more powerful integrated circuits (ICs) to build the advanced computing, communication, networking, and electronic systems of the modern Information Age.

One of the fundamental axioms of the current technology revolution is Moore's Law—articulated by Gordon Moore—which states that the number of transistors on an IC doubles every 18 months. Meeting that expectation has required device geometries to shrink with each successive IC generation. This drive to continually reduce feature sizes has traditionally meant that new technologies must be deployed to enable ever-increasing levels of device complexity. Currently, mature semiconductor products are produced with 0.25- or 0.18-micron geometries, while production of more advanced devices are rapidly transitioning to 0.13-micron processes.

To wire the transistors together on advanced integrated circuits, semiconductor manufacturers are faced with the challenge of using more and more levels of metal separated by interlevel dielectrics. At these extremely small dimensions, traditional designs using aluminum conductors and silicon dioxide dielectrics experience serious resistance and capacitance problems that erode device performance. In response to this challenge, the semiconductor industry is experiencing a significant technology shift that is delivering narrower line widths and greater packing densities while dramatically reducing interconnect complexity and cost. This new technology revolution is developing improved production systems, improved lithography technologies and, most importantly, fundamental changes in the conductive and insulating materials as well as the process of patterning interconnect structures.

Copper (Cu) has received considerable attention as a potential interconnect material because it exhibits intrinsically superior electromigration resistance and lower resistivity compared to conventional aluminum metallization. However, development of a process for patterning copper presents an important technical challenge for implementation of copper in ICs. Even when so-called Damascene process flows are used to avoid the need for subtractive patterning of Cu, there will be other steps that require etchback or removal of Cu such as chemical mechanical planarization (CMP).

A number of approaches relating to dry etching have been investigated. One approach involves the reaction of copper with a chlorine-containing gas and removal of the resulting by-products, such as CuClₓ. This process typically requires a temperature in the range of 225° C.-350° C. to desorb copper chloride during reactive ion etching under a Cl₂-based plasma. To reduce the process temperature, laser-induced etching of copper employing UV irradiation with a Cl₂-based inductively coupled plasma process has been introduced to enhance the copper desorption rate at lower substrate temperatures.

### SUMMARY

In certain aspects, the invention features methods for removing a material from a substrate by exposing the material to a removal agent (e.g., an etchant or other cleaning agent) dissolved in a supercritical or near supercritical fluid. More specifically, the invention features methods for etching copper from a substrate by first oxidizing portions of the copper to form copper oxide and then delivering a suitable etchant solution to the copper oxide under supercritical or near supercritical conditions to etch the copper oxide. For example, spurious copper deposits formed on metal deposition tools and other semiconductor process tools can be cleaned by sequential oxidation of the copper deposits followed by etching the oxide by exposure to an etchant solution in a supercritical fluid.

In one aspect, the invention features methods of etching materials from substrates, by dissolving an etchant into a solvent to form a solution, exposing the substrate to the solution such that the etchant in the solution removes material from the substrate, wherein during the exposure the solution is maintained in a supercritical or near-supercritical phase. Embodiments of the invention can include one or more of the following features.

The etchant can include a diketone etchant (e.g., hexafluoropentanedione). The diketonate etchant can be a non-fluorinated diketone etchant (e.g., tetramethylheptanedione and/or tetramethyloctanedione). The solvent can be or include CO₂. The material can be a metal oxide (e.g., copper oxide). The substrate can be silicon, a metal or a metal nitride. In some embodiments, the substrate can be a thin film (e.g., a metal or a metal nitride film) disposed on a layer of a base material material (e.g., silicon).

The method can also include depositing a derivative of the etched material onto the substrate. The removed material (e.g., copper oxide) can be reduced to provide the derivative (copper). The solution can include a reducing agent (e.g., hydrogen).

In certain embodiments, the method can further include exposing a precursor of the material (e.g., a metal, such as copper) to a reagent (e.g., an oxidizing agent, such as oxygen and/or a peroxide) to form the material (e.g., a metal oxide, such as copper oxide) on the substrate. The solvent can be the reagent. Oxidation of the material can occur while exposing the substrate to the solution. The metal portions can be simultaneously oxidized and etched.

In another aspect, the invention features methods of depositing a metal film onto a substrate, by maintaining supercritical carbon dioxide and a chelating agent in contact with the substrate to remove an oxide layer from a metal surface of the substrate, thereby forming a precleaned substrate, and depositing the metal film on the precleaned substrate without exposing the precleaned substrate to a material which oxidizes the metal surface of the precleaned substrate. Embodiments of these methods may include one or more of the aforementioned features.

In a further aspect, the invention features methods of patterning a metal layer, by selectively oxidizing portions of the metal layer to form metal oxide portions, and exposing the metal oxide portions to a solution including an etchant to remove the metal oxide portions from the metal layer thereby patterning the metal layer. During the exposure, the solution is maintained in a supercritical or near-supercritical phase. Embodiments of these methods may include one or more of the aforementioned features.

As used herein, a “supercritical solution” (or solvent) is one in which the temperature and pressure of the solution (or solvent) are greater than the respective critical temperature and pressure of the solution (or solvent). A supercritical condition for a particular solution (or solvent) refers to a condition in which the temperature and pressure are both respectively greater than the critical temperature and critical pressure of the particular solution (or solvent).

A “near-supercritical solution” (or solvent) is one in which the reduced temperature (actual temperature measured in Kelvin divided by the critical temperature of the solution (or solvent) measured in Kelvin) and reduced pressure (actual pressure divided by critical pressure of the solution (or solvent)) of the solution (or solvent) are both greater than 0.8 but the solution (or solvent) is not a supercritical solution. A near-supercritical condition for a particular solution (or solvent) refers to a condition in which the reduced temperature and reduced pressure are both respectively greater than 0.8 but the condition is not supercritical. Under ambient conditions, the solvent can be a gas or liquid. The term solvent is also meant to include a mixture of two or more different individual solvents.

As used herein, “etching” is a chemical reactive process for selectively removing material from a substrate, where the substrate can include any number of underlayers including Si wafers, dielectrics, metal films, polymeric materials etc

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

### DESCRIPTION OF DRAWINGS

FIG. 1 is a schematic of an embodiment of a system for etching a layer on a substrate using a supercritical solution.

FIG. 2(a)-2(d) are perspective views of different stages of patterning a layer on a substrate using a supercritical solution etch step.

FIG. 3 is an X-ray Photoelectron Spectroscopy (XPS) sputter depth profile of a wafer prior to etching the wafer.

FIG. 4 is an XPS sputter depth profile of the wafer after etching with a supercritical solution of hexafluoroacetylacetonate (H(hfac)).

FIG. 5 is an XPS survey spectrum of the wafer after etching with the supercritical solution of H(hfac).

FIG. 6 is a XPS sputter profile of a similar wafer after etching with a supercritical solution of tetrametylheptanedione (TMHD).

FIG. 7 is an XPS survey spectrum of the wafer after etching with the supercritical solution of TMHD.

FIG. 8 is a plot showing the thickness of copper oxide as a function of etch time for a supercritical solution of trimethyloctanedione (TMOD).

Like reference symbols in the various drawings indicate like elements.

### DETAILED DESCRIPTION

The invention is based, in part, on the discovery that materials (e.g., metals, metal oxides, semiconductors, and organic compounds) can be etched using supercritical solutions of an etchant. Contaminant materials, such as native oxides, can be efficiently removed from the surface of metal layers on a substrate, such as a silicon wafer. By selectively etching portions of layers, supercritical etching solutions can be used to pattern layers, e.g., to form vias and/or trenches in metal layers on semiconductor substrates. Additional process steps can be carried out before, during, and/or after etching.

For example, supercritical fluid solutions can be used to remove copper oxide from a copper layer. Typically, on exposure to air or other oxidizing environments, a surface of a copper layer will oxidize to form a layer of copper oxide. In semiconductor devices, for example, such copper oxide layers can have a deleterious effect on the nucleation, growth and adhesion of materials subsequently deposited on the copper layer, on the conductivity between the copper layer and subsequent layers, and ultimately, on device performance. Notably, these deleterious effects can be problematic for, e.g., interconnect structures, deposited on and/or between a copper layer. Accordingly, it is often desirable to etch the copper oxide layer from the copper layer prior to subsequent process steps when building a semiconductor device.

In the new methods, copper oxide can be etched using supercritical CO₂ solutions of β-diketones, such as hexafluoropentanedione H(hfac), and other chelating agents (i.e., substances that are capable of forming a chelate with a metal ion) such as pentanedione and trifluoropentanedione. Suitable copper oxide etchants also include non-fluorinated diketones, such as tetramethylheptanedione (TMHD) and trimethyloctanedione (TMOD). Both organic and inorganic acids can also be used to etch copper oxide. Examples of organic acids include hydroxy acids such as glycolic acid and citric acid, amino acids such as glycine and lysine, as well as acetic acid, oxalic acid, and formic acid. Hydrofluoric acid is an example of an inorganic acid.

In addition to copper oxide, other materials can also be etched using a supercritical etchant solution. For example, oxides of other metals, such as aluminum oxide and/or indium tin oxide can be etched using supercritical etchant solutions. In other examples, suitable supercritical solutions can be used to remove polymeric layers from a substrate. Etchants for polymers include peroxides such as hydrogen peroxide. More generally, supercritical fluid solutions can be used to remove any material from a substrate, so long as a suitable solvent/solute combination can be used under supercritical or near super critical conditions. For example, supercritical acid solutions can be used to etch metals and metal oxides from a substrate. Supercritical acid and supercritical peroxide solutions can be used to etch organic films including polymers from a substrate.

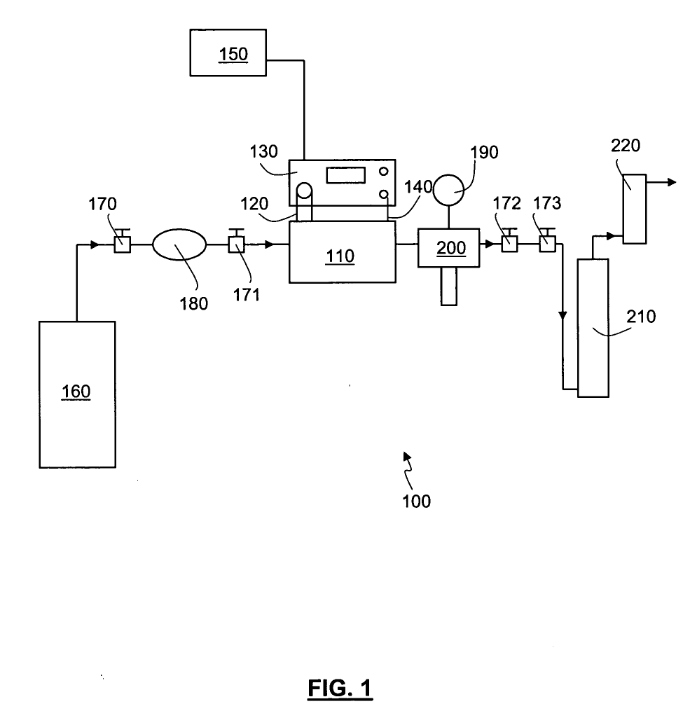

FIG. 1 shows a system 100 for supercritical fluid etching. System 100 includes a reaction vessel 110, in which a sample (not shown) is placed. A heating tape 120 is run from a temperature controller 130 into reaction vessel 110. Temperature controller 130 controls the temperature of heating tape 120, which heats the inside of reaction vessel 110. A thermocouple 140, connected to temperature controller 130, senses the temperature of reaction vessel 110 and provides temperature controller 130 with a feedback signal for adjusting the temperature of heating tape 120. Accordingly, temperature controller 130 controls the temperature of reaction vessel 110 within a narrow, pre-determined temperature range. Temperature controller 130 is powered by a power supply 150.

A high-pressure syringe pump 160 supplies reaction vessel 110 with solvent. A valve 170 controls flow of solvent from syringe pump 160 to reaction vessel 110. An etchant is introduced into the solvent using sample loop 180. Another valve 171 controls flow of solvent from sample loop 180 to reaction vessel 110.

Two outlet valves 172 and 173 control flow of solvent out of reaction vessel 110. A pressure sensor 190, positioned between reaction vessel 110 and outlet valves 172 and 173, provides a reading of the pressure inside reaction vessel 110. A rupture disk 200 is also positioned between reaction vessel 110 and outlet valves 172 and 173 to prevent over-pressurization of the reaction vessel.

Using system 100, a copper oxide layer, for example, is etched using the following procedure.

A single substrate having a copper layer with an oxidized surface layer is placed inside reaction vessel 110. Reaction vessel 110 is purged with nitrogen. Temperature controller 130 ramps the temperature of reaction vessel 110 to the process temperature. Once the reaction vessel is heated, syringe pump 160 fills the reaction vessel with heated (e.g., between 50° C. and 100° C.) CO₂.

A user then places an amount of the etchant in sample loop 180. The etchant dissolves in the CO₂ and the syringe pump pumps the CO₂ solution through sample loop 180 and into reaction vessel 110 until the pressure in the reaction vessel reaches a predetermined value (e.g., sufficient pressure so that, at its present temperature, the CO₂ is under supercritical or near supercritical conditions). The reaction vessel is held at the desired temperature and pressure for a certain time period, after which the reaction vessel is allowed to cool to ambient temperature and the CO₂ is vented through an activated carbon bed 210 and a liquid absorb test tube 220. Activated carbon bed 210 and liquid absorb test tube 220 minimize undesirable emission of etching by-products into the environment.

The amount of etchant placed in the sample loop is determined according to the sample size, desired etch rate, and solubility of the etchant in the solvent. Solubility of the etchant at the etching conditions can be verified in a variable volume view cell, which is well known in the art (e.g., McHugh et al, Supercritical Fluid Extraction: Principles and Practice; Butterworths, Boston, 1986). Known quantities of etchant and supercritical solvent are loaded into the view cell, where they are heated and compressed to conditions at which a single phase is observed optically. Pressure is then reduced isothermally in small increments until phase separation (either liquid-vapor or solid-vapor) is induced.

The temperature and pressure of the process depend on the etchants and choice of solvent. Generally, temperature is less than 300° C. (e.g., less than 200° C.) and often less than 100° C. (such as 80° C. or less), while the pressure is typically between 50 and 500 bar (e.g., between 100 and 400, 100 to 150, or 150 to 250 bar). A temperature gradient between the substrate and solution can also be used to enhance flow between the reactor walls and the substrate.

Solvents useful as supercritical fluids are well known in the art and are sometimes referred to as dense gases (Sonntag et al., Introduction to Thermodynamics, Classical and Statistical, 2nd ed., John Wiley & Sons, 1982, p. 40). At temperatures and pressures above certain values for a particular substance (defined as the critical temperature and critical pressure, respectively), saturated liquid and saturated vapor states are identical and the substance is referred to as a supercritical fluid. Solvents that are supercritical fluids are less viscous than liquid solvents by one to two orders of magnitude. When cleaning using a supercritical solution, the low viscosity of the supercritical solvent facilitates improved transport (relative to liquid solvents) of the etchants to, and etch by-products away, from the substrate. Furthermore, many etchants that might be useful in chemical vapor etching (CVE) are not sufficiently volatile to produce the high vapor phase concentrations required for efficient CVE. For example, it would be desirable to use non-flourinated diketones, such as tetramethylheptanedione, as agents but these compounds are significantly less volatile than their fluorinated analogues. Moreover, many etchants can produce metal chelates upon reaction with the metal oxide surface that do not readily desorb from the surface and result in by-product deposition limited kinetics that in turn limit etch rate. Again, this phenomenon is typically more acute for desirable non-fluorinated species compared to their fluorinated counterparts. In other cases, suitable etchants, including fluorinated diketones, exhibit limited solubility in desirable liquid solvents. However, the same etchants, such as H(hfac), are freely soluble in supercritical carbon dioxide. Generally, a supercritical solvent can be composed of a single solvent or a mixture of solvents, including for example a small amount (<5 mol %) of a polar liquid co-solvent such as methanol.

It is important that the etchants are sufficiently soluble in the supercritical solvent to allow homogeneous transport of the etchants. Solubility in a supercritical solvent is generally proportional to the density of the supercritical solvent. Ideal conditions for critical fluid etching include a supercritical solvent density of at least 0.1 to 0.2 g/cm³ or a density that is at least one third of the critical density (the density of the fluid at the critical temperature and critical pressure).

Due to the high solubility of etchants, metal chelates, and other by-products produced by reaction of the etchant with the metal oxide surface in the supercritical solvent, and due to the transport properties of the supercritical solution, supercritical fluid etching can exhibit enhanced etch rates compared to conventional etching techniques. For example, the kinetics of copper oxide etching with H(hfac) can be limited by desorption of the reaction product (Cu(hfac)₂) at temperatures above 210° C. (Lee et al., Thin Solid Films, 392, 122-127 (2001)) Since Cu(hfac)₂ is readily soluble in supercritical carbon dioxide, the use of supercritical etchant solutions usually mitigates this problem.

Table 1 below lists some examples of solvents along with their respective critical properties. These solvents can be used by themselves or in conjunction with other solvents to form the supercritical solvent in critical fluid etching. Table 1 lists the critical temperature, critical pressure, critical volume, molecular weight, and critical density for each of the solvents.

TABLE 1
Critical Properties of Selected Solvents

| | T_{c} | P_{c} | V_{c} | Molecular | ρ_{c} |
|---|---|---|---|---|---|
| Solvent | (K) | (atm) | (cm/mol) | Weight | (g/cm³) |
| CO₂ | 304.2 | 72.8 | 94.0 | 44.01 | 0.47 |
| C₂H₆ | 305.4 | 48.2 | 148 | 30.07 | 0.20 |
| C₃H₈ | 369.8 | 41.9 | 203 | 44.10 | 0.22 |
| n-C₄H₁₀ | 425.2 | 37.5 | 255 | 58.12 | 0.23 |
| n-C₅H₁₂ | 469.6 | 33.3 | 304 | 72.15 | 0.24 |
| CH₃—O—CH₃ | 400 | 53.0 | 178 | 46.07 | 0.26 |
| CH₃CH₂OH | 516.2 | 63.0 | 167 | 46.07 | 0.28 |
| H₂0 | 647.3 | 12.8 | 65.0 | 18.02 | 0.33 |
| C₂F₆ | 292.8 | 30.4 | 22.4 | 138.01 | 0.61 |

To describe conditions for different supercritical solvents, the terms “reduced temperature,” “reduced pressure,” and “reduced density” are used. Reduced temperature, with respect to a particular solvent, is temperature (measured in Kelvin) divided by the critical temperature (measured in Kelvin) of the particular solvent, with analogous definitions for pressure and density. For example, at 333 K and 150 atm, the density of CO₂ is 0.60 g/cm³; therefore, with respect to CO₂, the reduced temperature is 1.09, the reduced pressure is 2.06, and the reduced density is 1.28. Many of the properties of supercritical solvents are also exhibited by near-supercritical solvents, which refers to solvents having a reduced temperature and a reduced pressure both greater than 0.8, but not both greater than 1 (in which case the solvent would be supercritical). One set of suitable conditions for etching with supercritical fluid solutions include a reduced temperature of the supercritical or near-supercritical solvent of between 0.8 and 1.6 and a critical temperature of the fluid of less than 150° C.

Carbon dioxide (CO₂) is a particularly good choice of solvent for critical fluid etching. Its critical temperature (31.1° C.) is close to ambient temperature, and thus allows the use of moderate process temperatures (<80° C.). It is also unreactive with most precursors used in CVE and is an ideal medium for running reactions between gases and liquids or solid substrates. Other suitable solvents include, for example, ethane or propane, which may be more suitable than CO₂ in certain situations, e.g., when using precursors that can react with CO₂, such as complexes of low-valent metals containing strong electron-donating ligands (e.g., phosphines).

In some embodiments, additional solutes can be included in the supercritical solution. For example, a reducing agent, e.g., H₂, can be included in a supercritical etching solution for etching copper oxide. This reducing agent can reduce the etching by-product, e.g., Cu(hfac)₂, thereby redepositing the copper onto the substrate. Reductions can be induced by other reducing agents including alcohols such as ethanol, silanes and sulfides such as H₂S.

In some embodiments, a substrate can be pretreated prior to etching a layer of material away from the substrate. Such embodiments include cases where the layer to be etched is in the form of a precursor. This precursor layer should be converted into a layer of a material that can be etched by the etchant. For example, a copper layer can be oxidized to form a copper oxide layer, which can be subsequently etched using a suitable etchant, such as H(hfac). Such an oxidation step can be performed using methods known in the art, e.g., by exposing the copper layer to O₂ plasma.

Alternatively, or additionally, such an oxidation step can be performed under supercritical conditions. For example, one or more oxidizing agents (e.g., hydrogen peroxide or oxygen) can be dissolved in a solvent. The substrate is then exposed to this solution under supercritical or near-supercritical conditions. In some cases, the supercritical fluid and/or contaminants in the supercritical fluid can have oxidizing properties, and no additional oxidizing agents are needed. In embodiments where the layer is oxidized under supercritical conditions, the oxidation step can be performed prior to or concurrently with the etching step.

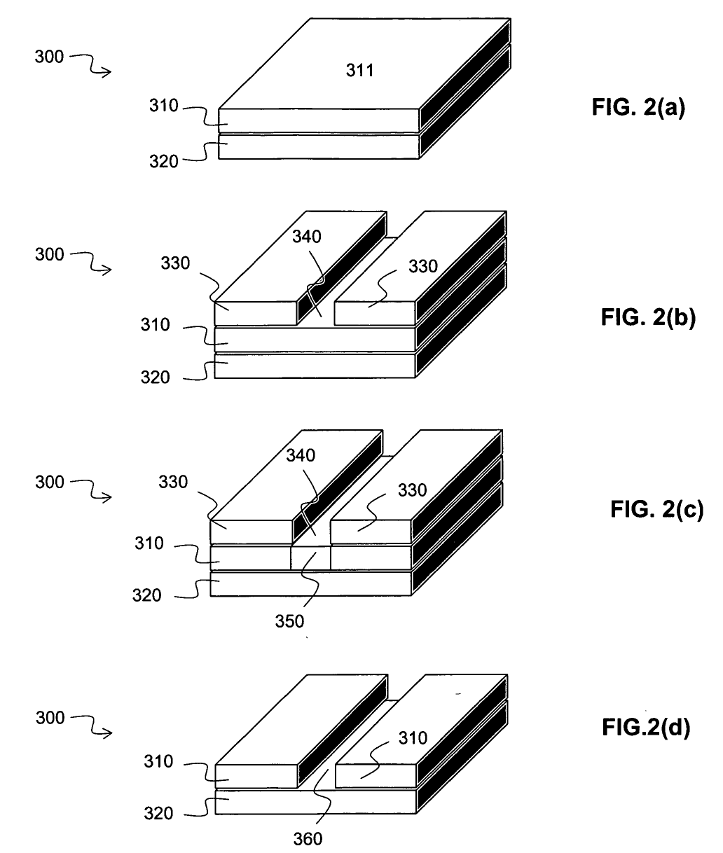

In some embodiments, supercritical etching can be used to pattern a layer of material on a substrate. Supercritical etching can be used as a process step in the lithographic manufacturing processes commonly used to manufacture ICs. An illustrative example, wherein a channel is etched into a metal layer on a substrate, is shown in FIGS. 2(a)-(d).

Referring to FIG. 2(a), an article includes a planar metal layer 310 (e.g., copper) deposited on a substrate 320, such as a silicon wafer. More generally, article 300 can include any number of intermediate layers (not shown) between metal layer 310 and substrate layer 320. Metal layer 310 has a top surface 311, which initially remains exposed.

Referring to FIG. 2(b), a photoresist layer 330 is deposited on surface 311. Photoresist layer 310 can be deposited using methods known in the art, such as spin coating. Photoresist layer 310 can be a positive or negative photoresist. Using an appropriate photomask, photoresist layer 330 is exposed to radiation and subsequently developed to form a channel 340 in the photoresist layer. Channel 340 exposes a portion of surface 311.

Referring to FIG. 2(c), article 300 is exposed to an oxidizing agent. Photoresist layer 330 largely prevents the oxidizing agent from reacting with underlying metal layer 340. However, the oxidizing agent oxidizes the portion of metal layer 310 exposed by channel 340, forming a metal oxide channel 350 in metal layer 310. Subsequently, article 300 is exposed to a supercritical etchant solution, which removes metal oxide channel 350 from metal layer 310.

At any stage after the oxidizing step, the remaining photoresist layer 330 can be cleaned from metal layer 310. This cleaning step can be performed before, during, or after the supercritical etching step. For example, after patterning a copper layer by selectively etching the copper layer using a photoresist, the residual photoresist can be cleaned off the copper layer by exposure to an appropriate cleaning agent. Suitable cleaning agents for many polymeric photoresists include organic solvents, such as acetone. In some cases, additives such as peroxides can be added to etch or degrade the polymeric film. Such cleaning steps can also be performed under supercritical conditions, prior to removing the substrate from the reactor.

Cleaned article 300 is shown in FIG. 2(d), and includes substrate 320 and now-patterned metal layer 310, which includes a channel 360.

In some embodiments, the etched layer can be treated in one or more additional post-etch steps. Post-etch steps include additional cleaning steps and/or deposition steps. For example, an additional layer can be deposited onto patterned metal layer 310 using techniques known in the art. These techniques include chemical vapor deposition (CVD), sputtering, and chemical fluid deposition (CFD). CFD in particular, which is described in U.S. patent application Ser. No. 09/704,935, entitled “CHEMICAL FLUID DEPOSITION FOR THE FORMATION OF METAL AND METAL ALLOY FILMS ON PATTERNED AND UNPATTERNED SUBSTRATES,” filed by Watkins et al., can be used to deposit a conformal layer on top of patterned layer 310. As CFD also involves exposing a substrate to a supercritical or near supercritical solution, such a deposition step can be performed using the same apparatus as used to etch metal layer 310. Besides the obvious economic benefit provided by using the same apparatus, not having to move the substrate between process steps can have the added benefit of limiting exposure of the newly-etched layer to contaminants and/or environmental changes prior to depositing additional layers thereon.

More generally, subsequent process steps (e.g., depositing a film, such as a metal film) on the surface of an etched substrate can be performed without exposing the etched substrate to a reagent (e.g., oxygen in air, where the etched material is an oxide), which would react with the etched surface (e.g., would oxidize the etched surface).

While the foregoing embodiments have been directed to IC processing, embodiments of the invention can include other applications. For example, critical fluid etching can be used to clean contaminants from tools and/or work pieces. As an illustrative example, consider a tool, e.g., a CFD reactor or an electron beam evaporation system, used for depositing copper onto a substrate. After prolonged use, exposed surfaces of components of such a tool can become contaminated with residual copper. Rather than replace these components, the owner can have the components cleaned by etching the copper from the surfaces using the foregoing methods (i.e., first oxidizing the copper to form copper oxide and etching the copper oxide). For the case of a CFD reactor, the tool can be cleaned in place. Cleaning using supercritical fluids can be particularly advantages for intricate components and/or components having non-planar surfaces. The low viscosity and fluid nature allow the supercritical fluid to conform to the shape of the component, and facilitate transport of the etchant to and by-products away from the contaminated surface.

### EXAMPLES

The invention is further described in the following examples, which do not limit the scope of the invention described in the claims.

Chemicals

Tetrametylheptanedione (TMHD) and hexafluoroacetylacetonate H(hfac) were obtained from Sigma-Aldrich, Inc. Trimethyloctanedione (TMOD) was obtained from Inorgtech, Inc (Mildenhall, Suffolk, UK). All chemicals were used as received. Carbon dioxide (Coleman grade, 99.99+% purity) was obtained form Merrian-Graves (West Springfield, Mass.) and used as received. Substrates for the etching experiments were prepared as follows. 2000 Å thick copper films were deposited onto silicon wafers by sputtering. The wafers were then subjected to thermal oxidation at 150° C. in an atmosphere of 1 torr of oxygen and 4 torr of argon to produce surface films of copper oxide approximately 100-150 Å thick. These test structures are referred to herein as Si/copper/copper oxide multi-layer stacks.

### Example 1

### Etching of Copper Oxide with H(hfac) in a Batch Reactor

A 1.1 cm×7.5 cm section of a Si/copper/copper oxide multi-layer stack (150 Å copper oxide) was loaded into a 15 ml stainless-steel high-pressure vessel within a glove box. The vessel was removed from the glove box, purged with N₂ and heated to 150° C. CO₂ was then transferred to the vessel from a high-pressure syringe pump (ISCO Inc., Lincoln, Nebr.), which was heated to 65° C. at a pressure of 138 bar. H(hfac) was loaded into a 0.2 ml sample loop. CO₂ was then pumped through the sample loop into the reaction vessel using the syringe pump until the vessel pressure reached 152 bar. The total mass of CO₂ transferred to the vessel was approximately 3.56 g yielding an 8.27 weight % solution of H(hfac) in CO₂. The reactor was held at these conditions for approximately 5 minutes. The reactor was then allowed to cool and the contents were vented through an activated carbon bed. The multi-layer film was then removed from the vessel and exposed to the atmosphere.

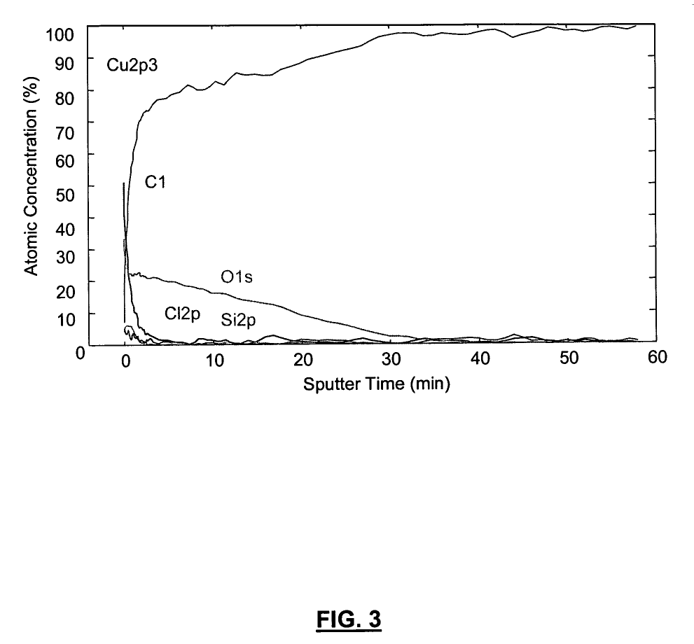

After etching, the film was reflective and exhibited a bright copper color. Over time, exposure to the atmosphere produced a native oxide at the exposed copper surface. To evaluate the efficacy of the etching reaction, a control sample (unetched Si/copper/copper oxide multi-layer) and the etched wafer were characterized by X-ray Photoelectron Spectroscopy (XPS) using sputter depth profiles at identical conditions. FIG. 3 shows an XPS depth profile of the wafer before etching. It took approximately 35 minutes to sputter through the copper film.

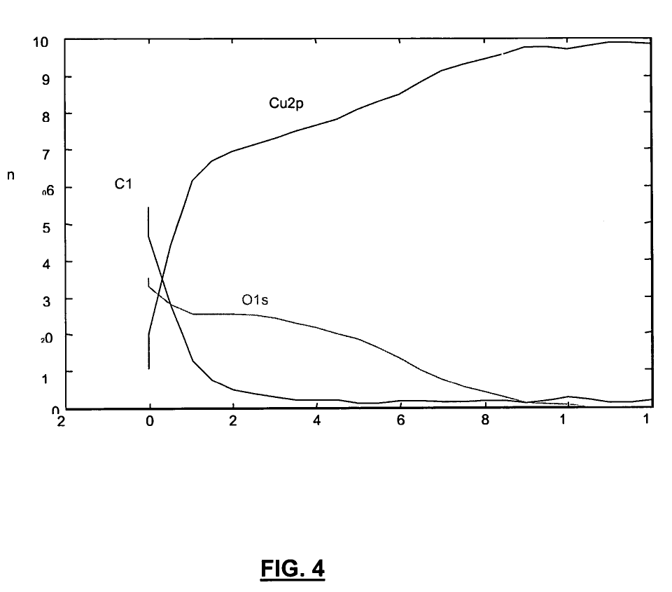

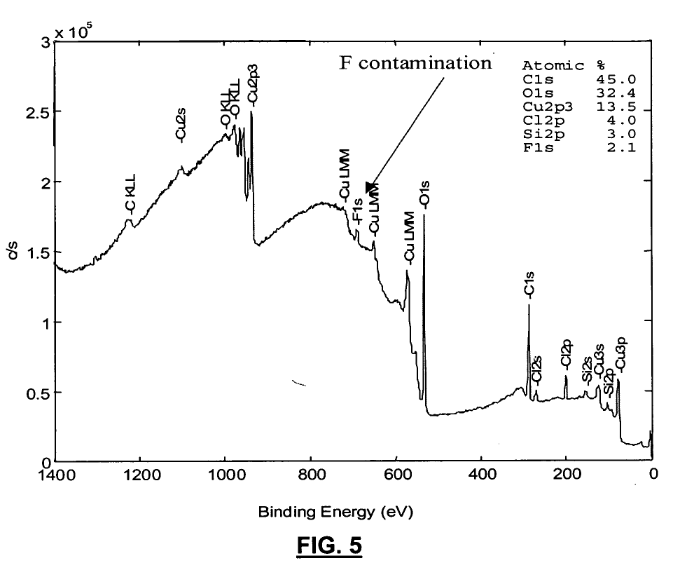

FIG. 4 shows an XPS depth profile of the wafer after etching. It took approximately nine minutes to sputter through the oxide film. The results indicate stripping of copper oxides during the etching step. The presence of copper oxide on the etched film surface is as expected due to exposure to the atmosphere after treatment. Fluorine contamination is evident in the XPS survey spectrum shown in FIG. 5.

### Example 2

### Batch Etching of Copper Oxide with TMHD

A 1.0 cm×5.5 cm section of a Si/copper/copper oxide multi-layer stack and 0.179 g TMHD was loaded into a 15 ml high pressure vessel within a glove box. The vessel was sealed, removed from the glove box and heated to 80° C. CO₂ was transferred to the reactor at a pressure of 275.8 bar from an ISCO high pressure syringe pump heated to 80° C. The concentration of TMHD in CO₂ was approximately 1.66% by weight. After four hours the vessel was vented through an activated carbon bed. The multi-layer stack was removed from the vessel and exposed to the atmosphere. After etching, the film was reflective and exhibited a bright copper color. The film was analyzed by XPS under the same conditions to those used in Example 1.

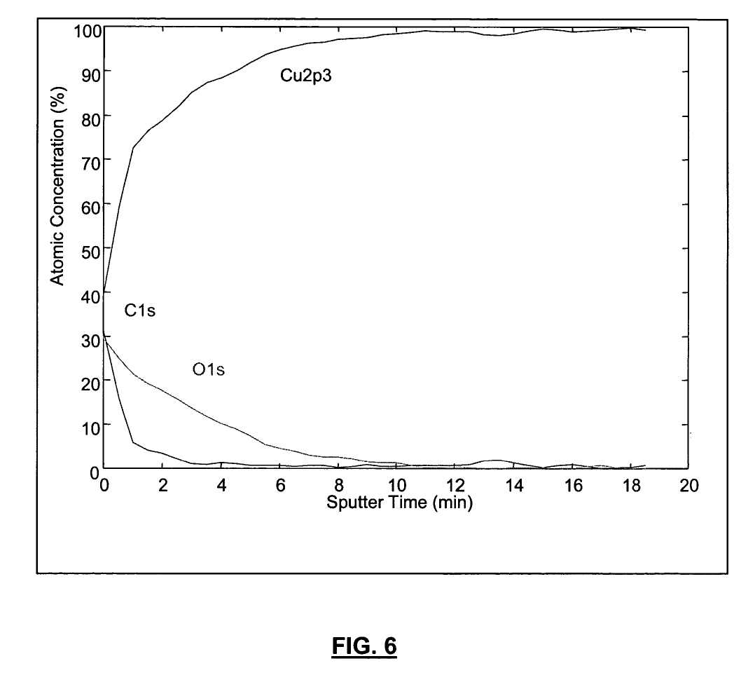

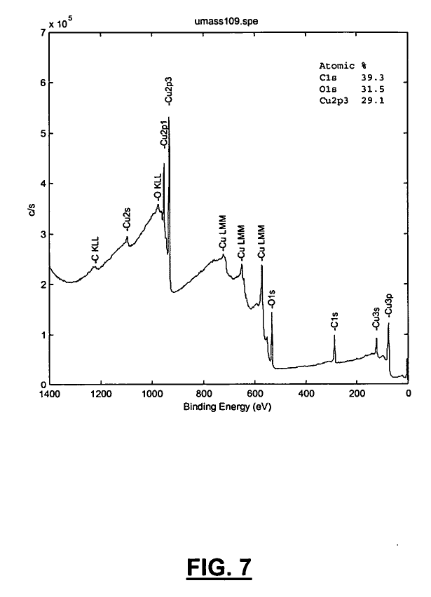

The results of this analysis are shown in FIG. 6. It took approximately nine minutes to sputter through the oxide film after etching compared to approximately 35 minutes for the untreated wafer. Unlike the case described in Example 1, no fluorine contamination was evident in an XPS survey spectrum acquired on the film etched with TMHD, the results of which are shown in FIG. 7. Accordingly, using a non-fluorinated etchant mitigates fluorine contamination of the substrate.

### Example 3

### Batch Etching of Copper Oxide with TMOD (5 Minute Etch)

A 1.0 cm×5.5 cm section of a Si/copper/copper oxide multi-layer stack was loaded into a 20 ml high pressure vessel. The vessel was sealed, purged with CO₂ at 69 bar and heated to 60° C. CO₂ transferred to the reactor at a pressure of 241 bar. TMOD was loaded into a 0.2 ml high-pressure loop. CO₂ was then pumped through the sample loop into the high-pressure vessel, raising its pressure from 241 bar to 275.8 bar. The total amount of CO₂ transferred to the high-pressure vessel was 9.13 g. The final concentration of TMOD in CO₂ was 1.96% by weight. The Si/Copper/Copper oxide multi-layer stack was exposed to the TMOD/CO₂ solution for 5 minutes. The high-pressure vessel was then purged with CO₂ to remove the TMOD/CO₂ solution. The thickness of the copper oxide layer on both a control sample and the etched sample were analyzed by electrochemical reduction using a Surface Scan QC100 instrument (ECI Tech, Inc., East Rutherford, N.J.). The results are provided in Table 2. The copper oxide layer was 155 Å thick (on average) on the sample etched by the TMOD/CO₂ solution.

TABLE 2
Results of etching copper oxide using TMOD

| Copper Oxide Thickness | Etch Time |
|---|---|
| [Å] | [minutes] |
| 73 | 5 |
| 71 | 5 |
| 46 | 10 |
| 54 | 10 |
| 155 | control |
| 155 | control |

### Example 4

### Batch Etching of Copper Oxide with TMOD (10 Minute Etch)

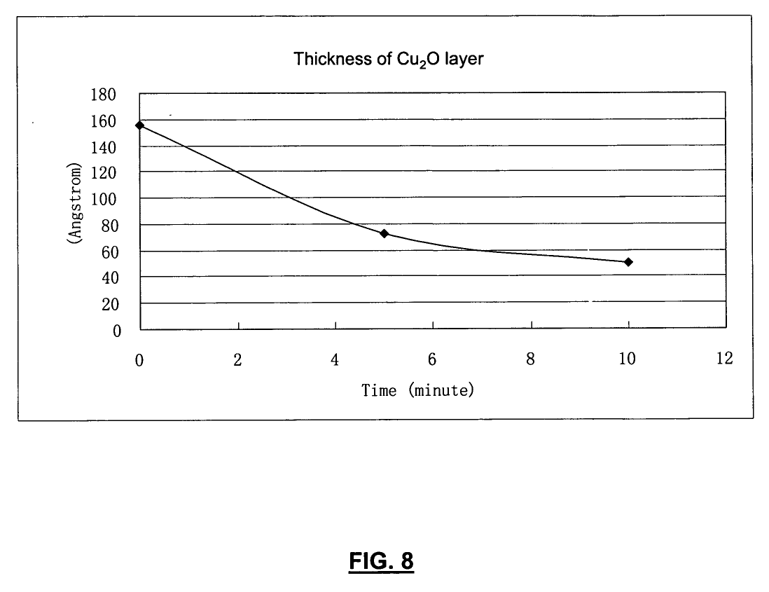

A 1.0 cm×5.5 cm section of a Si/copper/copper oxide multi-layer stack was loaded into a 20 ml high pressure vessel. The vessel was sealed, purged with CO₂ at 69 bar and heated to 60° C. CO₂ was transferred to the reactor at the pressure 241 bar. TMOD was loaded into a 0.2 ml high-pressure loop. CO₂ was then pumped through the sample loop into the high-pressure vessel raising its pressure from 241 bar to 275.8 bar. The total amount of CO₂ transferred to the high-pressure vessel was 9.13 g. The final concentration of TMOD in CO₂ was 1.96% by weight. The Si/copper/copper oxide multi-layer stack was exposed to the TMOD/CO₂ solution for 10 minutes. The high-pressure vessel was then purged with CO₂ to remove the TMOD/CO₂ solution. The thickness of the copper oxide layer on both a control sample and the etched sample were analyzed by electrochemical reduction using a Surface Scan QC100 instrument (ECI Tech, Inc). The results are provided in table 2. The copper oxide layer was 155 Å thick in the control sample and 50 Å thick (on average) on the sample etched by the TMOD/CO₂ solution. The results of Example 3 and Example 4 are summarized in FIG. 8.

### Example 5

### Etching and Subsequent Deposition of Cu

A 15 nm thick conformal Cu film on an etched silicon wafer containing narrow trenches and vias is prepared by sputtering. Upon exposure to the atmosphere, the surface of the film is oxidized. The wafer containing the film is loaded into a supercritical deposition chamber suitable for CFD and exposed to a solution of 2% TMOD in CO₂ at 200° C. for five minutes yielding an oxide free Cu surface and the Cu(tmod)₂ chelation product, which is dissolved in CO₂. Hydrogen is then transferred into the reactor whereupon Cu(tmod)₂ is reduced and Cu is deposited onto the clean copper surface. The trenches and vias on the patterned wafer are filled by CFD in which the hydrogen assists reduction of Cu(tmod)₂.

### Example 6

### Cleaning of Surfaces by Sequential Oxidation and Etching

A solution of hydrogen peroxide in CO₂ at 60° C. and 200 bar is introduced into a CFD deposition tool that is contaminated by spurious Cu metal deposits. The Cu deposits are oxidized to copper oxide by contact with the supercritical solution. After five minutes, the solution is purged from the reactor. A 2% solution of TMOD in CO₂ is introduced into the deposition chamber and maintained at 200° C. and 250 bar. The copper oxides are etched by contact with the TMOD/CO₂ solution leaving substantially Cu and Cu oxide free surfaces within the deposition tool.

### Example 7

### Cleaning of Surfaces by Simultaneous Oxidation and Etching

A mixture of 2 wt. % TMOD dissolved in a supercritical mixture of 3 vol. % O₂ in CO₂ at 100° C. and 200 bar is introduced into a CFD deposition tool that is contaminated by spurious Cu metal deposits. The Cu deposits are oxidized to copper oxide by contact with the supercritical solution and the incipient copper oxides are etched by the solution, producing a metal chelate byproduct. After fifteen minutes, the solution is purged from the reactor leaving substantially Cu and Cu oxide free surfaces within the deposition tool.

### OTHER EMBODIMENTS

A number of embodiments of the invention have been described. Nevertheless, it will be understood that various modifications may be made without departing from the spirit and scope of the invention. Accordingly, other embodiments are within the scope of the following claims.

What is claimed is:

1. A method of etching a material from a substrate, the method comprising:
dissolving an etchant into a solvent to form a solution;
exposing the substrate to the solution such that the etchant in the solution removes material from the substrate;
wherein during the exposure the solution is maintained in a supercritical or near-supercritical phase.

2. The method of claim 1, wherein the etchant comprises a diketone etchant.

3. The method of claim 2, wherein the etchant comprises hexafluoropentanedione.

4. The method of claim 2, wherein the etchant comprises a non-fluorinated diketone etchant.

5. The method of claim 4, wherein the etchant comprises tetramethylheptanedione.

6. The method of claim 4, wherein the etchant comprises tetramethyloctanedione.

7. The method of claim 1, wherein the solvent comprises CO₂.

8. The method of claim 1, wherein the material comprises a metal oxide.

9. The method of claim 8, wherein the material comprises copper oxide.

10. The method of claim 1, wherein the substrate comprises silicon, a metal, or a metal nitride.

11. The method of claim 1, wherein the substrate comprises a thin film disposed on a layer of a base material.

12. The method of claim 11, wherein the thin film comprises a metal or a metal nitride

13. The method of claim 11, wherein the base material comprises silicon.

14. The method of claim 1, further comprising depositing a derivative of the etched material onto the substrate.

15. The method of claim 14, wherein the removed material is reduced to provide the derivative.

16. The method of claim 15, wherein the removed material comprises copper oxide and the derivative comprises copper.

17. The method of claim 1, wherein the solution comprises a reducing agent.

18. The method of claim 17, wherein the reducing agent is hydrogen.

19. The method of claim 1, further comprising exposing a precursor of the material to a reagent to form the material on the substrate.

20. The method of claim 19, wherein the material comprises a metal oxide, the precursor comprises a metal, and the reagent comprises an oxidizing agent.

21. The method of claim 20, wherein the solvent is the oxidizing agent.

22. The method of claim 20, wherein the oxidizing agent is oxygen.

23. The method of claim 20, wherein the oxidizing agent comprises a peroxide.

24. The method of claim 20, wherein the oxidation occurs while exposing the substrate to the solution.

25. A method of depositing a metal film on a substrate, the method comprising:
maintaining supercritical carbon dioxide and a chelating agent in contact with the substrate to remove an oxide layer from a metal surface of the substrate, thereby forming a precleaned substrate; and
depositing the metal film on the precleaned substrate without exposing the precleaned substrate to a material which oxidizes the metal surface of the precleaned substrate.

26. A method of patterning a metal layer, the method comprising:
selectively oxidizing portions of the metal layer to form metal oxide portions; and
exposing the metal oxide portions to a solution including an etchant to remove the metal oxide portions from the metal layer thereby patterning the metal layer;
wherein during the exposure the solution is maintained in a supercritical or near-supercritical phase.

27. The method of claim 24, wherein the metal portions are simultaneously oxidized and etched.
